(19) United States
(12) Patent Application Publication
(10) Pub. No.: US 2005/0162895 A1
(43) Pub. Date: Jul. 28, 2005

(54) Molecular memory arrays and devices

(76) Inventors: Werner G. Kuhr, Denver, CO (US); Antonio R. Gallo, Colorado Springs, CO (US)

Correspondence Address: HOGAN & HARTSON LLP, ONE TABOR CENTER, SUITE 1500, 1200 SEVENTEENTH ST, DENVER, CO, 80202, US

(21) Appl. No.: 10/766,304

(22) Filed: Jan. 28, 2004

(51) Int. Cl. G11C 11/00

(52) U.S. Cl. 365/151

(57) ABSTRACT

Molecular memory arrays and devices in accordance with the present invention include a molecular memory element which comprises a switching device, a bit line and word line coupled to the switching device and a molecular storage device comprising a first electrode, a second electrode and a molecular material between the first and second electrodes wherein the switching device is coupled to the first electrode.

### BACKGROUND OF THE INVENTION

1. Field of the Invention

This invention relates to memory devices, such as static, permanent and dynamic random access memory. In particular, this invention relates to molecular memory cells, molecular memory arrays, and electronic devices including molecular memory.

2. Relevant Background

Advances in semiconductor processing and device design have resulted in computing devices being incorporated with a seemingly endless variety of tools and machines ranging from conventional programmable computers to communication equipment and entertainment devices. Irrespective of its end purpose, a computing device is generally made up of three main components, a central processing unit (CPU), random access memory (RAM), and an addressing and communication mechanism enabling data exchange between the CPU and the RAM. In a computing device, data is stored, communicated and manipulated in the form of signals (e.g., voltage, current, optical and the like). The CPU contains circuitry for logically manipulating the signals whereas the memory contains circuitry for storing the signals before, during and after the CPU's manipulation of those signals.

Conventional CPUs, memory devices and data communication mechanisms are mass produced as solid state electronic devices. Although sometimes referred to as “semiconductor devices”, solid state electronic devices rely on electrical behavior of solids including metals, semiconductors, and insulators. The techniques and equipment for producing solid state devices have improved dramatically over time to enable the production of devices such as switches, capacitors, resistors, and interconnections with sub-micron scale features.

Performance of the memory components of a computing device is becoming an increasingly important determinant of overall system performance. Larger quantities of memory enable a greater variety of applications and functions to be implemented by the computing device and may reduce or eliminate the need for separate mass storage devices. Higher speed memory supports higher CPU processing frequencies, making the computing devices more useful for complex or real-time tasks. Denser memory devices support a growing variety of battery-powered electronic devices such as laptop computers, PDAs, multifunction cellular telephones, and the like. At the same time, many of these applications benefit from reduced power consumption.

In many cases improvements in semiconductor processing technology have had the effect of improving each of these important figures to make denser, larger, faster and more power efficient memory devices. In many cases, the solid state electronic behavior of the devices improves as the devices become smaller. Unfortunately, conventional silicon-based memory, such as DRAM memory, has reached a point where continued reduction in the size of conventional semiconductor memory cells is expected to adversely affect at least some of these important parameters.

One reason for the reduced speed and increased power consumption at smaller dimensions is that memory devices usually implement a capacitor for each stored bit of information. A capacitor is a charge storage device formed by conductive plates that are separated by an insulator. As capacitors become smaller the quantity of charge that can be stored is reduced. To serve as a reliable memory device, a capacitor must have sufficient capacity to hold a signal at a level that can be later reliable detected as data. Moreover, capacitors are inherently “leaky” devices in that some of the charge stored in a capacitor dissipates or leaks over time. Memory devices based on smaller capacitors are more sensitive to leakage problems because they simply have less charge that can be lost before the stored data becomes irretrievable.

To overcome the transient nature of capacitive storage, memory devices use refresh circuitry that frequently reads out a stored signal, amplifies it to a higher level, and stores it back into the capacitor. As a capacitors shrink, the rate at which the capacitor needs to be refreshed increases. In turn, higher capacitor refresh rates reduce the percentage of time that a memory cell is available for reading and writing data. Moreover, a greater percentage of the total power consumption of the memory device is then used to refresh the memory. Even when the device is in a dormant or inactive state, traditional DRAM requires continuous refreshing and therefore continuous power consumption. Accordingly, researchers are actively seeking new ways of storing data signals that overcome the problems associated with smaller capacitors in conventional capacitor based memory devices.

Memory cell designers have attempted to maintain low refresh rates in smaller memory cells by boosting the amount of capacitance that can be formed in a given amount of chip area. Boosting capacitance often involves increasing the surface area of the capacitor's charge holding material, which is very difficult to do when the overall size of the capacitor is shrinking. While designers have had some success at controlling surface area by forming the charge holding material into three-dimensional trench and stacked capacitor designs, it is unlikely that these techniques can be relied for continued progress rendering larger capacitances in smaller devices. The solid state electronic behaviors upon which device performance is predicated begin to break down as the dimensions of various device features become smaller such that a capacitor can no longer store sufficient charge for sufficient time to be useful in a memory device.

Another problem facing memory designers trying to increase information density (e.g., the amount of information that can be stored in a given area of the memory chip). Each memory cell of a conventional solid state capacitor can only store one bit of information. Accordingly, it would be desirable to have a memory device with improved information storage density achieved by having a memory cell that can reliably store a plurality of discrete states.

In view of the above, it is apparent that a need exists for memory devices, such as dynamic random access memory, that overcome limitations imposed by conventional solid state memory design. In particular, there is a need for molecular memory cells, molecular memory arrays, and electronic devices including molecular memory. Further, there is a need for molecular memory devices that can be manufactured using techniques that are compatible with existing semiconductor manufacturing practices so that semiconductor devices and interconnections can be manufactured monolithically with molecular memory devices.

### SUMMARY OF THE INVENTION

Briefly stated, an embodiment of the present invention comprises a molecular memory element that includes a switching device, a bit line and a word line coupled to the switching device, and a molecular storage device accessible through the switching device. The molecular storage device is capable of being placed in two or more discrete states, wherein the molecular storage device is placed in one of the discrete states by signals applied to the bit and word line. The molecular storage device comprises a first electrode, a second electrode and a molecular material between the first and second electrode.

The present invention also relates to molecular memory arrays comprising a plurality of molecular storage elements where each molecular storage element is capable of being placed in two or more discrete states. A plurality of bit lines and word lines are coupled to the plurality of molecular storage elements such that each molecular storage element is coupled to and addressable by at least one bit line and at least one word line.

In another aspect, the present invention contemplates a molecular memory device comprising an addressable array of molecular storage elements. An address decoder receives a coded address and generates word line signals corresponding to the coded address. A word line driver is coupled to the address decoder and produces amplified word line signals. The amplified word line signals control switches that selectively couple members of the array of molecular storage elements to bit lines. Read/write logic coupled to the bit lines determines whether the molecular memory devices is in a read mode or a write mode. In a read mode, sense amplifiers coupled to each bit line detect an electronic state of the selectively coupled molecular storage elements and produce a data signal on the bit line indicative of the electronic state of the selectively coupled molecular storage elements. In a write mode, the read/write logic drives a data signal onto the bit lines and the selectively coupled molecular storage elements.

The present invention also contemplates devices including logic integrated with embedded molecular memory devices such as application specific integrated circuit (ASIC) and system on chip (SOC) devices and the like. Such implementations comprise one or more functional components formed monolithically with and interconnected to molecular memory devices. The functional components may comprise solid state electronic devices and/or molecular electronic devices.

In particular embodiments, the molecular storage device is implemented as a stacked structured formed subsequent to and above a semiconductor substrate having active devices formed therein. In other embodiments, the molecular storage device is implemented as a micron or nanometer sized hole in a semiconductor substrate have active devices formed therein. The molecular storage device is fabricated using processing techniques that are compatible with the semiconductor substrate and previously formed active devices in the semiconductor substrate. The molecular storage device comprises, for example, an electrochemical cell having two or more electrode surfaces separated by a an electrolyte (e.g., a ceramic or solid electrolyte). Storage molecules (e.g., molecules having one or more oxidation states that can be used for storing information) are coupled to an electrode surface within the electrochemical cells. Examples of storage molecules include monomeric porphyrins, ferrocene-derivatived porphyrins, trimeric porphyrins, or triple-decker sandwich porphyrins, among other compounds.

Additional novel features are set forth in the description that follows, and in part will become apparent to those skilled in the art upon examination of the following specification or may be learned by the practice of the invention. The features and advantages of the invention may be realized and attained by means of the instrumentalities, combinations, and methods particularly pointed out in the appended claims. In particular, it should be noted that through particular implementations of a molecular storage device into the molecular memory arrays and devices of the present invention, it is possible to provide a device which is sufficiently large so as to actually obviate the need for a sense amplifier.

As may be utilized herein, the following definitions may be applied wherein the term “oxidation” refers to the loss of one or more electrons in an element, compound, or chemical substituent/subunit. In an oxidation reaction, electrons are lost by atoms of the element(s) involved in the reaction. The charge on these atoms must then become more positive. The electrons are lost from the species undergoing oxidation and so electrons appear as products in an oxidation reaction. An oxidation is taking place in the reaction Fe3+(aq)→Fe3+(aq)+e− because electrons are lost from the species being oxidized, Fe3+(aq), despite the apparent production of electrons as “free” entities in oxidation reactions. Conversely the term reduction refers to the gain of one or more electrons by an element, compound, or chemical substituent/subunit.

An “oxidation state” refers to the electrically neutral state or to the state produced by the gain or loss of electrons to an element, compound, or chemical substituent/subunit. In a preferred embodiment, the term “oxidation state” refers to states including the neutral state and any state other than a neutral state caused by the gain or loss of electrons (reduction or oxidation).

The term “multiple oxidation states” means more than one oxidation state. In preferred embodiments, the oxidation states may reflect the gain of electrons (reduction) or the loss of electrons (oxidation).

The terms “different and distinguishable” when referring to two or more oxidation states means that the net charge on the entity (atom, molecule, aggregate, subunit, etc.) can exist in two different states. The states are said to be “distinguishable” when the difference between the states is greater than thermal energy at room temperature (e.g. 0° C. to about 40° C.).

The term “tightly coupled” when used in reference to a subunit of a multi-subunit (e.g., polymeric) storage molecule of this invention refers to positioning of the subunits relative to each other such that oxidation of one subunit alters the oxidation potential(s) of the other subunit. In a preferred embodiment the alteration is sufficient such that the (non-neutral) oxidation state(s) of the second subunit are different and distinguishable from the non-neutral oxidation states of the first subunit. In a preferred embodiment the tight coupling is achieved by a covalent bond (e.g. single, double, triple, etc.). However, in certain embodiments, the tight coupling can be through a linker, via an ionic interaction, via a hydrophobic interaction, through coordination of a metal, or by simple mechanical juxtaposition. It is understood that the subunits could be so tightly coupled that the redox processes are those of a single supermolecule.

The term “electrode” refers to any medium capable of transporting charge (e.g. electrons) to and/or from a storage molecule. Preferred electrodes are metals or conductive organic molecules. The electrodes can be manufactured to virtually any 2-dimensional or 3-dimensional shape (e.g. discrete lines, pads, planes, spheres, cylinders, etc.).

The term “fixed electrode” is intended to reflect the fact that the electrode is essentially stable and unmovable with respect to the storage medium. That is, the electrode and storage medium are arranged in an essentially fixed geometric relationship with each other. It is of course recognized that the relationship alters somewhat due to expansion and contraction of the medium with thermal changes or due to changes in conformation of the molecules comprising the electrode and/or the storage medium. Nevertheless, the overall spatial arrangement remains essentially invariant. In a preferred embodiment this term is intended to exclude systems in which the electrode is a movable “probe” (e.g. a writing or recording “head”, an atomic force microscope (AFM) tip, a scanning tunneling microscope STM) tip, etc.).

The term “working electrode” is used to refer to one or more electrodes that are used to set or read the state of a storage medium and/or storage molecule.

The term “reference electrode” is used to refer to one or more electrodes that provide a reference (e.g. a particular reference voltage) for measurements recorded from the working electrode. In preferred embodiments, the reference electrodes in a memory device of this invention are at the same potential although in some embodiments this need not be the case.

The term “electrically coupled” when used with reference to a storage molecule and/or storage medium and electrode refers to an association between that storage medium or molecule and the electrode such that electrons move from the storage medium/molecule to the electrode or from the electrode to the storage medium/molecule and thereby alter the oxidation state of the storage medium/molecule. Electrical coupling can include direct covalent linkage between the storage medium/molecule and the electrode, indirect covalent coupling (e.g. via a linker), direct or indirect ionic bonding between the storage medium/molecule and the electrode, or other bonding (e.g. hydrophobic bonding). In addition, no actual bonding may be required and the storage medium/molecule may simply be contacted with the electrode surface. There also need not necessarily be any contact between the electrode and the storage medium/molecule where the electrode is sufficiently close to the storage medium/molecule to permit electron tunneling between the medium/molecule and the electrode.

The term “redox-active unit” or “redox-active subunit” refers to a molecule or component of a molecule that is capable of being oxidized or reduced by the application of a suitable voltage.

The term “redox-active” molecule refers to a molecule or component of a molecule that is capable of being oxidized or reduced by the application of a suitable voltage.

The term “subunit”, as used herein, refers to a redox-active component of a molecule.

The terms “storage molecule” or “memory molecule” refer to a molecule having one or more oxidation states that can be used for the storage of information (e.g. a molecule comprising one or more redox-active subunits). Preferred storage molecules have two or more different and distinguishable non-neutral oxidation states.

The term “storage medium” refers to a composition comprising two or more storage molecules. The storage medium can contain only one species of storage molecule or it can contain two or more different species of storage molecule. In preferred embodiments, the term “storage medium” refers to a collection of storage molecules. Preferred storage media comprise a multiplicity (at least 2) of different and distinguishable (preferably non-neutral) oxidation states. The multiplicity of different and distinguishable oxidation states can be produced by the combination of different species of storage molecules, each species contributing to said multiplicity of different oxidation states and each species having a single non-neutral oxidation state. Alternatively or in addition, the storage medium can comprise one or more species of storage molecule having a multiplicity of non-neutral oxidation states. The storage medium can contain predominantly one species of storage molecule or it can contain a number of different storage molecules. The storage media can also include molecules other than storage molecules (e.g. to provide chemical stability, suitable mechanical properties, to prevent charge leakage, etc.).

The term “electrochemical cell” typically refers to a reference electrode, a working electrode, a redox-active molecule (e.g. a storage medium), and, if necessary, some means (e.g., a dielectric or a conducting electrolyte) for providing electrical conductivity between the electrodes and/or between the electrodes and the medium. In some embodiments, the dielectric is a component of the storage medium.

The terms “memory element”, “memory cell”, or “storage cell” refer to an electrochemical cell that can be used for the storage of information. Preferred “storage cells” are discrete regions of storage medium addressed by at least one and preferably by two electrodes(e.g. a working electrode and a reference electrode). The storage cells can be individually addressed (e.g. a unique electrode is associated with each memory element) or, particularly where the oxidation states of different memory elements are distinguishable, multiple memory elements can be addressed by a single electrode. The memory element can optionally include a dielectric (e.g. a dielectric impregnated with counterions).

The term “storage location” refers to a discrete domain or area in which a storage medium is disposed. When addressed with one or more electrodes, the storage location may form a storage cell. However if two storage locations contain the same storage media so that they have essentially the same oxidation states, and both storage locations are commonly addressed, they may form one functional storage cell.

“Addressing” a particular element refers to associating (e.g., electrically coupling) that memory element with an electrode such that the electrode can be used to specifically determine the oxidation state(s) of that memory element.

The terms “read” or “interrogate” refer to the determination of the oxidation state(s) of one or more molecules (e.g. molecules comprising a storage medium).

The term “refresh” when used in reference to a storage molecule or to a storage medium refers to the application of a voltage to the storage molecule or storage medium to re-set the oxidation state of that storage molecule or storage medium to a predetermined state (e.g. an oxidation state the storage molecule or storage medium was in immediately prior to a read).

The term “E_{1/2}” refers to the practical definition of the formal potential (E°) of a redox process as defined by E=E°+(RT/nF)1n(Dₒₓ/D_{red}) where R is the gas constant, T is temperature in K (Kelvin), n is the number of electrons involved in the process, F is the Faraday constant (96,485 Coulomb/mole), Dₒₓ is the diffusion coefficient of the oxidized species and D_{red} is the diffusion coefficient of the reduced species.

A “voltage source” is any source (e.g. molecule, device, circuit, etc.) capable of applying a voltage to a target (e.g. an electrode).

The phrase “output of an integrated circuit” refers to a voltage or signal produced by a one or more integrated circuit(s) and/or one or more components of an integrated circuit.

A “voltammetric device” is a device capable of measuring the current produced in an electrochemical cell as a result of the application of a voltage or change in voltage.

An “amperometric device” is a device capable of measuring the current produced in an electrochemical cell as a result of the application of a specific potential (“voltage”) for a period of time.

A “potentiometric device” is a device capable of measuring potential across an interface that results from a difference in the equilibrium concentrations of redox molecules in an electrochemical cell.

A “coulometric device” is a device capable of the net charge produced during the application of a potential field (“voltage”) to an electrochemical cell.

An “impedance spectrometer” is a device capable of determining the overall impedance of an electrochemical cell.

A “sinusoidal voltammeter” is a voltammetric device capable of determining the frequency domain properties of an electrochemical cell.

The term “porphyrinic macrocycle” refers to a porphyrin or porphyrin derivative. Such derivatives include porphyrins with extra rings ortho-fused, or ortho-perifused, to the porphyrin nucleus, porphyrins having a replacement of one or more carbon atoms of the porphyrin ring by an atom of another element (skeletal replacement), derivatives having a replacement of a nitrogen atom of the porphyrin ring by an atom of another element (skeletal replacement of nitrogen), derivatives having substituents other than hydrogen located at the peripheral (meso-, (3- or core atoms of the porphyrin, derivatives with saturation of one or more bonds of the porphyrin (hydroporphyrins, e.g., chlorins, bacteriochlorins, isobacteriochlorins, decahydroporphyrins, corphins, pyrrocorphins, etc.), derivatives obtained by coordination of one or more metals to one or more porphyrin atoms (metalloporphyrins), derivatives having one or more atoms, including pyrrolic and pyrromethenyl units, inserted in the porphyrin ring (expanded porphyrins), derivatives having one or more groups removed from the porphyrin ring (contracted porphyrins, e.g., corrin, corrole) and combinations of the foregoing derivatives (e.g. phthalocyanines, sub-phthalocyanines, and porphyrin isomers). Preferred porphyrinic macrocycles comprise at least one 5-membered ring.

The term “porphyrin” refers to a cyclic structure typically composed of four pyrrole rings together with four nitrogen atoms and two replaceable hydrogens for which various metal atoms can readily be substituted. A typical porphyrin is hemin.

The term “multiporphyrin array” refers to a discrete number of two or more covalently-linked porphyrinic macrocycles. The multiporphyrin arrays can be linear, cyclic, or branched.

The terms “sandwich coordination compound” or “sandwich coordination complex” refer to a compound of the formula L “M°-′, where each L is a heterocyclic ligand (as described below), each M is a metal, n is 2 or more, most preferably 2 or 3, and each metal is positioned between a pair of ligands and bonded to one or more hetero atom (and typically a plurality of hetero atoms, e.g., 2, 3, 4, 5) in each ligand (depending upon the oxidation state of the metal). Thus sandwich coordination compounds are not organometallic compounds such as ferrocene, in which the metal is bonded to carbon atoms. The ligands in the sandwich coordination compound are generally arranged in a stacked orientation (i.e., are generally cofacially oriented and axially aligned with one another, although they may or may not be rotated about that axis with respect to one another) (see, e.g., Ng and Jiang (1997) Chemical Society Reviews 26: 433-442). Sandwich coordination complexes include, but are not limited to “double-decker sandwich coordination compound” and “triple-decker sandwich coordination compounds”. The synthesis and use of sandwich coordination compounds is described in detail in U.S. Pat. No. 6,212,093E 1.

The term “double-decker sandwich coordination compound” refers to a sandwich coordination compound as described above where n is 2, thus having the formula L′-M′-LZ, wherein each of L1 and LZ may be the same or different (see, e.g., Jiang et al. (1999) J. Porphyrins Phthalocyanines 3: 322-328).

The term “triple-decker sandwich coordination compound” refers to a sandwich coordination compound as described above where n is 3, thus having the formula L′-M′ LZ-MZ-L3, wherein each of L1, LZ and L3 may be the same or different, and M1 and MZ may be the same or different (see, e.g., Arnold et al. (1999) Chemistry Letters 483-484).

A “linker” is a molecule used to couple two different molecules, two subunits of a molecule, or a molecule to a substrate.

A “substrate” is a, preferably solid, material suitable for the attachment of one or more molecules. Substrates can be formed of materials including, but not limited to glass, plastic, silicon, germanium, minerals (e.g. quartz), semiconducting materials (e.g. doped silicon, silicon oxides, doped germanium, etc.), ceramics, metals, metal oxides, etc.

The term “aryl” refers to a compound whose molecules have the ring structure characteristic of benzene, naphthalene, phenanthrene, anthracene, etc. (i.e., either the 6-carbon ring of benzene or the condensed 6-carbon rings of the other aromatic derivatives). For example, an aryl group may be phenyl or naphthyl (C₁₀H₉). It is recognized that the aryl group, while acting as substituent can itself have additional substituents (e.g. the substituents provided for S″ in the various Formulas herein).

The term “alkyl” refers to a paraffinic hydrocarbon group which may be derived from an alkane by dropping one hydrogen from the formula. Examples are methyl (CH₃—), ethyl (C₂H₅—), propyl (CH₃CH₂CH₂—), isopropyl ((CH₃)₂CH—).

The term “halogen” refers to one or the electronegative elements of group VIIB of the periodic table (fluorine, chlorine, bromine, iodine, astatine).

The term “nitro” refers to the NO₃ group.

The term “amino” refers to the NH₂ group.

The term “perfluoroalkyl” refers to an alkyl group where every hydrogen atom is replaced with a fluorine atom.

The term “perfluoroaryl” refers to an aryl group where every hydrogen atom is replaced with a fluorine atom.

The term “pyridyl” refers to an aryl group where one CH unit is replaced with a nitrogen atom.

The term “cyano” refers to the —CN group.

The term “thiocyanato” refers to the —SCN group.

The term “sulfoxyl” refers to a group of composition RS(O)— where R is some alkyl, aryl, cycloalkyl, perfluoroalkyl, or perfluoroaryl group. Examples include, but are not limited to methylsulfoxyl, phenylsulfoxyl, etc.

The term “sulfonyl” refers to a group of composition RSOZ- where R is some alkyl, aryl, cycloalkyl, perfluoroalkyl, or perfluoroaryl group. Examples include, but are not limited to methylsulfonyl, phenylsulfonyl, p-toluenesulfonyl, etc.

The term “carbamoyl” refers to the group of composition R1(RZ)NC(O)— where R1 and R2 are H or some alkyl, aryl, cycloalkyl, perfluoroalkyl, or perfluoroaryl group. Examples include, but are not limited to N-ethylcarbamoyl, NN-dimethylcarbamoyl, etc

The term “amido” refers to the group of composition R′CON(RZ)- where RI and RZ are H or some alkyl, aryl, cycloalkyl, perfluoroalkyl, or perfluoroaryl group. Examples include, but are not limited to acetamido, N-ethylbenzamido, etc.

The term “acyl” refers to an organic acid group in which the OH of the carboxyl group is replaced by some other substituent (RCO—). Examples include, but are not limited toacetyl, benzoyl, etc.

In preferred embodiments, when a metal is designated by “M” or “M+”, where n is an integer, it is recognized that the metal may be associated with a counterion.

The term “substituent” as used in the formulas herein, particularly designated by S or S° where n is an integer, in a preferred embodiment refer to redox-active groups (subunits) that can be used to adjust the redox potential(s) of the subject compound. Preferred substituents include, but are not limited to, aryl, phenyl, cycloalkyl, alkyl, halogen, alkoxy, alkylthio, perfluoroalkyl, perfluoroaryl, pyridyl, cyano, thiocyanato, nitro, amino, alkylamino, acyl, sulfoxyl, sulfonyl, amido, and carbamoyl. In preferred embodiments, a substituted aryl group is attached to a porphyrin or a porphyrinic macrocycle, and the substituents on the aryl group are selected from the group consisting of aryl, phenyl, cycloalkyl, alkyl, halogen, alkoxy, alkylthio, perfluoroalkyl, perfluoroaryl, pyridyl, cyano, thiocyanato, nitro, amino, alkylamino, acyl, sulfoxyl, sulfonyl, amido, and carbamoyl.

Particularly preferred substituents include, but are not limited to, 4-chlorophenyl, 3-acetamidophenyl, 2,4-dichloro-4-trifluoromethyl). Preferred substituents provide a redox potential range of less than about 5 volts, preferably less than about 2 volts, more preferably less than about 1 volt.

The phrase “provide a redox potential range of less than about X volts” refers to the fact that when a substituent providing such a redox potential range is incorporated into a compound, the compound into which it is incorporated has an oxidation potential less than or equal to X volts, where X is a numeric value.

The phrase “rapidly removed” when used in reference to a solvent comprising the organic molecule that is to be attached to the group IV element refers to a solvent that is substantially or completely removed within about 1 hour, more preferably within about 20 minutes, still more preferably within about 10 minutes, and most preferably within about 5 minutes, 2 minutes or 1 minute under particular conditions (e.g. at a particular temperature, vacuum, etc.).

A “high boiling solvent” refers to a solvent having a boiling point greater than about 130° C., preferably greater than about 150° C., more preferably greater than about 180° C., and most preferably greater than about 200° C.).

### BRIEF DESCRIPTION OF THE DRAWINGS

FIG. 1 illustrates an exemplary memory device and memory array in accordance with an embodiment of the present invention in block diagram form;

FIG. 2 illustrates an exemplary system on a chip (SOC) with embedded molecular memory in accordance with the present invention;

FIG. 3 illustrates an exemplary molecular memory cell in accordance with an embodiment of the present invention;

FIG. 4 shows a timing diagram useful in operating a memory array in accordance with the present invention;

FIG. 5 shows a simplified cross-section of a stacked capacitor embodiment molecular storage device

FIG. 6 shows a simplified cross-section of a “molehole” embodiment molecular storage device;

FIG. 7 and FIG. 8 are cyclic voltammograms that illustrate a current-voltage characteristic exemplary storage molecule implementations;

FIG. 9 illustrates a current-voltage characteristic of an exemplary molecular storage device in accordance with the present invention;

FIG. 10 schematically illustrates read/write circuitry useful in the present invention; and

FIG. 11 shows a memory device and supporting interface and control logic in accordance with a particular implementation.

FIGS. 12A through 12H show, respectively the formula for a redox-active molecule as a metallocene in FIG. 12A, particular embodiments thereof in the form of ferrocenes in FIGS. 12B through 12G and a porphyrin in FIG. 12H.

### DETAILED DESCRIPTION OF THE PREFERRED EMBODIMENTS

The present invention contemplates a number of device and system architectures that enable the use of molecular storage molecules to be integrated with and benefit from the technology developed for conventional microelectronics. At one level the present invention involves molecular memory elements that integrate storage molecules with switching logic that enables reading and writing to the storage molecules. At another extreme, the represent invention contemplates highly integrated circuits having logic devices, including data processing circuitry, integrated monolithically with molecular memory arrays to provide new and useful functions that leverage one or more the unique features of molecular memory such as lower power usage, superior data persistence, higher information density, and the like.

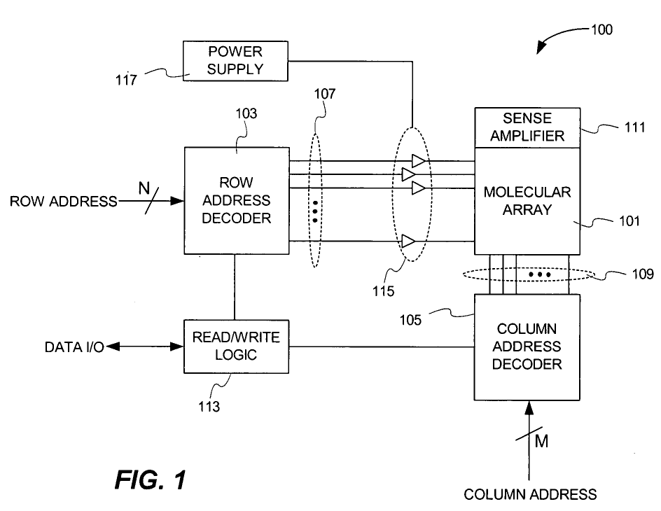

FIG. 1 shows a memory device 100 incorporating a molecular memory array 101. Molecular memory array 101 comprises an array of 2^{N} rows and 2^{M} column. Each of the 2^{N} rows is associated with a word line 107, while each of the 2^{M} columns is associated with a bit line 109. In a typical application the word lines 107 and bit lines 109 will intersect each other. A molecular memory device 300 (shown in FIG. 3) located at the intersection of each row and column. Molecular memory array 101 may include any number of molecular memory devices 300 arranged in any fashion that meets the needs of a particular application.

Memory device 100 is operated by receiving an N-bit row address into row address decoder 103 and an M-bit column address into column address decoder 105. row address decoder 103 generates a signal on one word line 107. Word lines 107 may include word line driver circuitry 115 that drives a high current signal onto word lines 107. Because word lines 107 tend to be long, thin conductors that stretch across much of the chip surface, it requires significant current and large power switches to drive a word lines signal. As a result, line driver circuits 115 are often provided with power supply 117 in addition to power supply circuits (not shown) that provide operating power for the other logic. Word line drivers 115, therefore, tend to involve large components and the high speed switching of large currents tends to create noise, stress the limits of power supplies and power regulators, and stress isolation structures.

In a conventional memory array there are more columns (bit lines) than rows (word lines) because during refresh operations, each word line is activated to refresh all of storage elements coupled to that word line. Accordingly, the fewer the number of rows, the less time it takes to refresh all of the rows. One feature of the present invention is that the molecular memory elements 300 can be configured to exhibit significantly longer data retention than typical capacitors, in the order of tens, hundreds, thousands or effectively, unlimited seconds. Hence, the refresh cycle can be performed orders of magnitude less frequently or omitted altogether. Accordingly, refresh considerations that actually affect the physical layout of a memory array 101 can be relaxed and arrays of various geometry can be implemented. For example, memory array 101 can readily be manufactured with a larger number of word lines, which will make each word line shorter. As a result, word line driver circuits 115 can be made smaller or eliminated because less current is required to drive each word line at a high speed. Alternatively or in addition, shorter word lines can be driven faster to improve read/write access times. As yet another alternative, each row of memory locations can be provided with multiple word lines to provide a mechanism for storing multiple states of information in each memory location

Sense amplifiers 111 are coupled to each bit line 109 and operate to detect signals on bit lines 109 that indicate the state of a memory element 300 coupled to that bit line, and amplify that state to an appropriate logic level signal. In one embodiment, sense amplifiers 111 may be implemented with substantially conventional designs as such conventional designs will operate to detect and amplify signals from a molecular memory element 300. Alternatively, unlike conventional capacitors, some molecular storage elements provide very distinct signals indicating their state. These distinct signals may reduce the need for conventional sense amplifier logic as the state signal from a molecular storage device can be more readily and reliably latched into buffers of read/write logic 113 than can signals stored in conventional capacitors.

Read/write logic 113 includes circuitry for placing the memory device 100 in a read or write state. In a read state, data from molecular array 101 is placed on bit lines 109 (with or without the operation of sense amplifiers 111), and captured by buffers/latches in read/write logic 113. Column address decoder 105 will select which bit lines 109 are active in a particular read operation. In a write operation, read/write logic 113 drives data signals onto the selected bit lines 109 such that when a word line is activated, that data overwrites any data already stored in the addressed memory element(s) 300.

A refresh operation is substantially similar to a read operation, however, the word lines 107 are driven by refresh circuitry (not shown) rather than by externally applied addresses. In a refresh operation, sense amplifiers 111, if used, drive the bit lines 109 to signal levels indicating the current state of the memory elements 300 and that value is automatically written back to the memory elements 300. Unlike a read operation, the state of bit lines 109 is not coupled to read/write logic 113 during a refresh. This operation is only required if the charge retention time of the molecules used is less than the operational life of the device used, for example, on the order of 10 years for Flash memory.

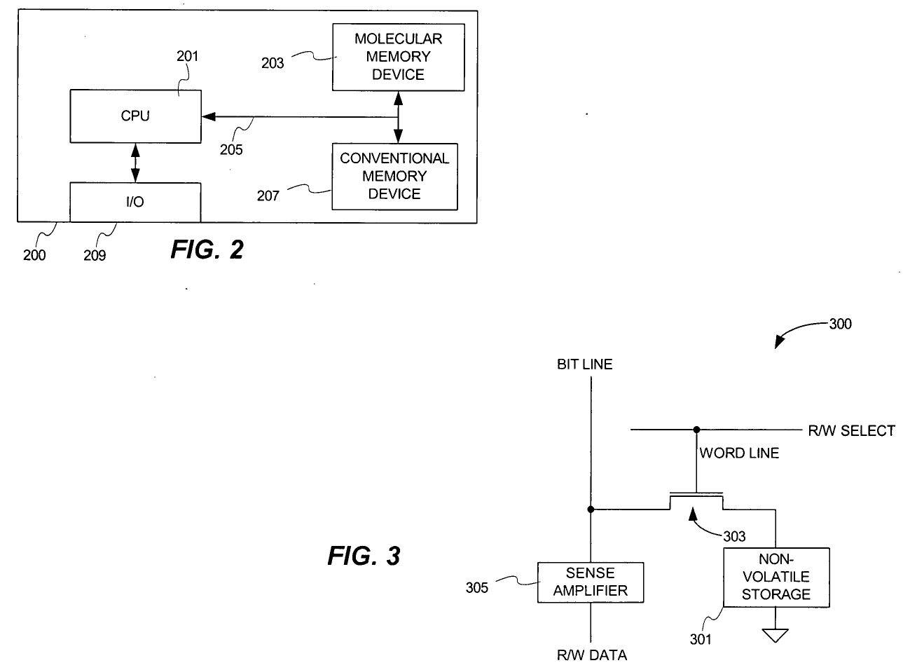

FIG. 2 illustrates an exemplary embedded system 200 that comprises a central processing unit 201 and molecular memory 203. A memory bus 205 couples CPU 201 and molecular memory device 203 to exchange address, data, and control signals. Optionally, embedded system 200 may also contain conventional memory 207 coupled to memory bus 205. Conventional memory 207 may include random access memory (e.g., DRAM, SRAM, SDRAM and the like), or read only memory (e.g., ROM, EPROM, EEPROM and the like). These other types of memory may be useful for caching data molecular memory device 203, storing operating system or BIOS files, and the like. Embedded system 200 may include one or more input/output (I/O) interfaces 209 that enable CPU 201 to communicate with external devices and systems. I/O interface 209 may be implemented by serial ports, parallel ports, radio frequency ports, optical ports, infrared ports and the like. Further, interface 209 may be configured to communicate using any available protocol including packet-based protocols.

FIG. 3 illustrates a memory element 300 in accordance with an embodiment of the present invention. Memory element 300 is akin to a widely used one transistor on capacitor (1T1C) memory element design, however, differs in that a molecular storage device 301, is employed. In particular embodiments, the molecular storage device is implemented as a stacked structured formed subsequent to and above a semiconductor substrate having active devices formed therein. In other embodiments, the molecular storage device is implemented as a micron or nanometer sized hole in a semiconductor substrate have active devices formed therein. The molecular storage device is fabricated using processing techniques that are compatible with the semiconductor substrate and previously formed active devices in the semiconductor substrate. The molecular storage device comprises, for example, an electrochemical cell having two or more electrode surfaces separated by an electrolyte (e.g., a ceramic or solid electrolyte or by direct contact with a metal or semiconductor structure). Storage molecules (e.g., molecules having one or more oxidation states that can be used for storing information) are coupled to an electrode surface within the electrochemical cells. Examples of storage molecules include monomeric porphyrins, ferrocene-derivatived porphyrins, trimeric porphyrins, porphyrin polymers or triple-decker sandwich porphyrins, among other compounds. Examples of suitable storage molecules are described in greater detail hereinafter.

When a word line is activated, access transistor 303 is placed in a conductive state thereby coupling molecular storage device 301 to its associated bit line. In many cases, the signal generated by molecular storage 301 is not sufficient to drive conventional logic devices. A sense amplifier 315 detects the signal generated by molecular storage 301 and amplifies that signal to an appropriate logic level (i.e., a signal compatible with other system logic). For example, using porphyrin storage molecules it is possible to construct storage devices 301 with stable oxidation states at +0.55V, +0.48V, +0.39V, +0.17V, −0.05V and −0.18V. More or fewer stable oxidation states may be provided in a given embodiment. The storage molecules can be placed in a selected one of these oxidation states by application of an appropriate voltage to a bit line 109, and while activating an appropriate word line 107. Once the storage device 301 is placed in the desired oxidation state, it will remain in that oxidation state for tens, hundreds, thousands or an indefinite number of seconds in particular applications.

During reading, a word line 107 is activated and the storage device 301 drives the bit line to a voltage that indicates its oxidation state. This is done in a manner very similar to that in which a capacitor performs the same operation. When the gate transistor is opened, the molecular storage device (MSD) is connected to the bit line. For example, the molecule has been written into an oxidized state, if the bit line is precharged to a value that is more negative than the oxidation potential of the molecule (with reference to the top metal of the MSD or counter electrode), and that molecule is in an oxidized state, current will flow from the molecule to the bit line (and electrons will flow from the bit line to the molecule) and the molecule is reduced once the transistor is closed. This will result in an accumulation of charge on the bit line, where the magnitude of the charge is determined by the number of molecules on the MSD and the oxidation state of each molecule (Q=nFN, Faraday's Law). The appearance of that charge will change the voltage on the bit line (V=Q/C), and that change in voltage can be distinguished by a voltage-sensing amplifier, as conventionally used in the art.

The bit line voltage during a read operation may vary from the oxidation state voltages due to parasitic effects and loading of the read circuitry, however, the circuitry is arranged to allow the stable oxidation states to be read distinctly. The bit line voltage may be read directly by external logic, or may be amplified to more conventional logic levels by sense amplifier 315. In particular implementations, the sense amplifier 315 may include multiple reference points (e.g. a multi-state sense amplifier) so that it produces stable multi-valued signals on the bit line. Alternatively, sense amplifier 315 may include analog-to-digital functionality that produces a plurality of logic-level binary outputs in response to the multi-value voltage signal read from a particular memory element 300.

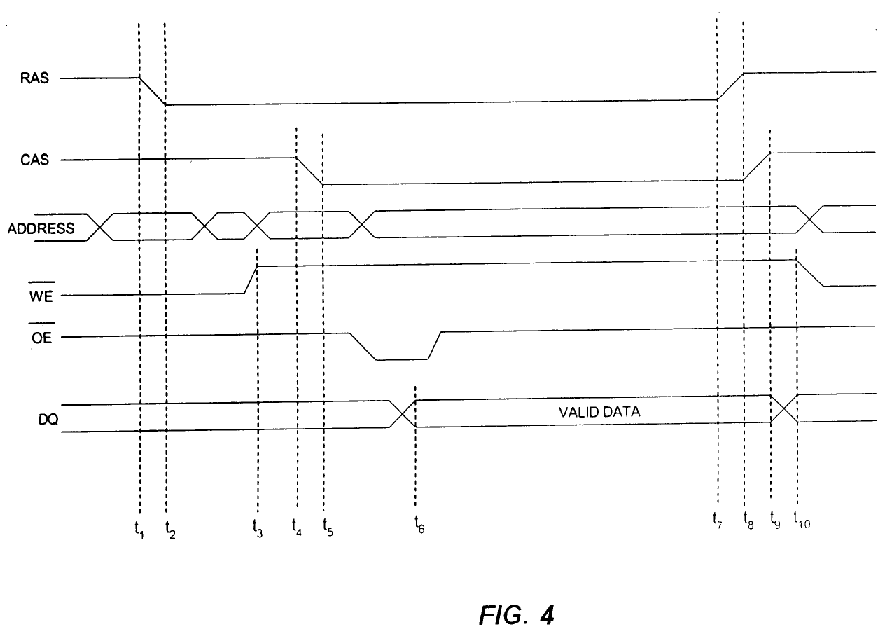

FIG. 4 illustrates an exemplary timing diagram for a read operation during operation of a memory in accordance with the present invention. The timing diagram of FIG. 4 is provided by way of example to show operation of an implementation that is analogous to a conventional DRAM operation. Other signal formats and control protocols are known and the present invention is readily adapted to these other formats. As shown in FIG. 4, row and column addresses are communicated in two phases. Row addresses are placed on the address bus, and a row address strobe (RAS) is generated, for example, by read/write logic 113. When the RAS signal transitions between times t1 and t2 when the row address is latched into row address decoder 103 (shown in FIG. 1) and a word line 107 is selected. RAS is held in the active state until the transition at t7-t8. In response to activation of the word line, sense amplifiers 111 operate to drive the bit lines to appropriate logic level signals.

At time t3 a write enable (WE) strobe is transitioned to an inactive state where it remains until the end of the write cycle at t10. The WE transition prevents the molecular array from being written to. Subsequently, column address are presented on the address bus. When the column address is stable, the column address strobe (CAS) transitions at times t4-t5 to initiate the capture and decoding of the column address by column address decoder 105 (shown in FIG. 1). After time t5, a bit line 109 or set of bit lines 109 is/are selected and remains selected until the CAS signal is removed by the CAS transition at times t8-t9. An output enable (OE) signal transitions to couple the selected bit lines 109 to the data I/O ports. At time t6 the valid data appears on the data lines. Valid data remains through the transitions of the RAS and CAS and WE signals to an inactive state.

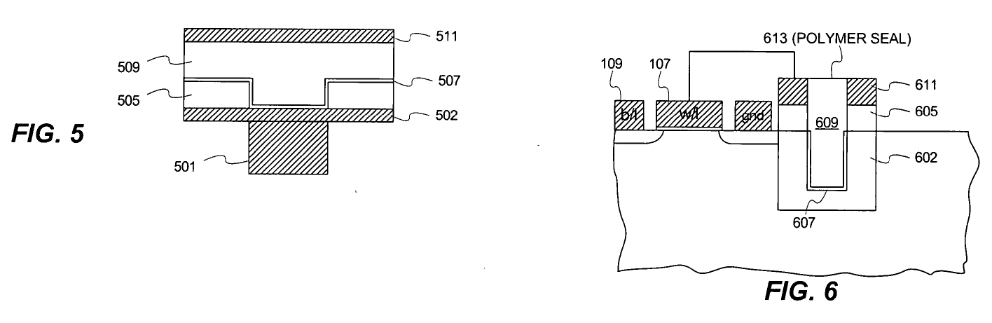

In the particular examples, the molecular storage device 301 is configured as an electrochemical cell having a reference electrode and a working electrode coupled through an electrolyte. FIG. 5 shows a stacked configuration for construction of a molecular storage device while FIG. 6 illustrates a trench or “molehole” implementation. In the stacked implementation of FIG. 5, the entire structure may be built on top of and electrically coupled to an electrode of an underlying semiconductor device. For example, conductive via or plug 501 may reach down through passivation and planarization layers of a semiconductor device to make electrical contact with a source/drain region of an access transistor 303. Conductive plug 501 may couple to a metal bond pad, or to the active region of a semiconductor device. In a particular example, plug 501 comprises tungsten, but may be manufactured using any metal, alloy, silicide, or other material that is available for implementing electrical connectivity.

Working electrode 503 comprises, for example, silicon, copper, aluminum, gold, silver, or other available conductor. While the working electrode may be a metal, it can also be a metaloxide, semiconductor or doped semiconductor. Other suitable materials include: Ti, Ta, TiO₂, TaO₂, SiO₂, W, WOₓ and the like. Working electrode 503 is preferably formed at the same time as other structures such as bond pads and interconnects for an integrated circuit. Processes and materials for forming plugs 501 and electrodes 503 are widely available in the semiconductor processing industry. In many integrated circuit processes, metal pads will be coated with insulating layer 505 which serves to protect and/or passivate working electrode 503. Insulating layer 505 may be implemented as a deposited oxide, silicon nitride, or the like. Layer 505 is patterned to expose a portion of working electrode 503, preferably in the same operation used to expose portions of bonding pads of the integrated circuit. The exposed portion of working electrode 503 defines an active area for the molecular storage device 301. It is contemplated that the present invention can be manufactured up through the formation and patterning of oxide 505 using industry standard process flows.

A thin layer 507 of storage molecules is formed on the active area of working electrode 503. This layer may range in thickness from 0.1 to 100 nanometers in particular examples. It is desirable to implement layer 507 as a self assembling monolayer (SAM). The active area of the molecules is lithographically defined by patterning layer 505 over the conductive material. An extensive library of derivatized porphyrins (˜250 compounds) is available as storage molecules for attachment to metalelectrodes suitable for use in layer 507. These compounds may comprise any of five different architectures: (1) monomeric porphyrins with different types of tethers, (2) ferrocene-derivatized porphyrins, (3) wing-shaped trimeric porphyrins, (4) porphyrin polymers, and (5) triple-decker sandwich porphyrins and polymers thereof. All of these porphyrinic architectures were found to form excellent quality self-assembled monolayers (SAMs). Once the molecules are attached, a thin (e.g., 50 to 200 nanometer) layer of metal, metaloxide or conductive electrolyte is applied to form electrolyte 509. Electrolyte 509 is the electrolyte for the oxidation-reduction cell. A metal layer 511 is deposited by evaporation, sputtering, or other deposition technique on to electrolyte layer 509. Metal layer 511 forms a reference electrode or counter electrode of the oxidation-reduction cell and comprises any well behaved electrochemical counter electrode material such as copper, silver, platinum and the like. Economics and semiconductor processes already developed will determine the metal of choice in a particular application.

In operation, storage molecules 507 are attached to and electrically coupled to the working electrode 503. The electrolyte 509, which may be a liquid, gel, or solid that is chemically compatible with the storage molecules and other conductors and insulators used in the device. Electrolyte 509 enables the transport of charge between the working and reference electrodes. For any given oxidation state and choice of storage molecules the electrochemical cell exhibits a distinctive electrochemical potential called the half-wave potential (E_{1/2}) or equilibrium potential. A given molecular storage device 301 will have two, three, four, or more distinctive E_{1/2}'s depending on the particular storage molecules chosen. This offers the potential of manufacturing a single infrastructure including read/write logic, address decoders, interconnect circuitry and the like that can be customized at a late state of manufacture by selecting the particular storage molecules for the device. Some adjustment of the electronics will be required to compensate for the particular characteristics of the chosen storage molecule, however, the manufacturing advantages are clear.

One advantage of the stacked architecture shown in FIG. 5 is that the bottom surface of the capacitor forms the electrode surface, and storage molecules are able form monolayers on this surface. Also, electrolyte layer 509 coats the storage molecules, essentially encapsulating them and protecting them from subsequent steps. Moreover, metal is never deposited directly onto the molecular layer, thereby preventing damage and other problems associated architectures that expose the storage molecules during or after processing to metal contamination. Further, the structure of FIG. 5 provides an easy way to implement a three-dimensional architecture in that subsequent layers of metal, insulator and the like are added after manufacture of the underlying semiconductor-based microelectronic devices while also preventing short-circuits.

FIG. 6 illustrates an implementation of a storage device 301 in which an electrochemical cell is formed in a trench structure, also called a “molehole” structure. A trench extends into substrate 601, through an overlying dielectric layer 605 (e.g., oxide) and counter electrode 611. The walls of the trench are exposed and provides a surface contact to which storage molecules 607 can be assembled. Storage molecules 607 and electrolyte 609 are added and the structure then be covered by a polymer 613 to seal the array.

Each word line 107 is connected to the counter electrode 611 of the memory cells in a row, while each bit line is connected to the drains of the memory cells in a column. The ground voltage is connected to the source regions of the memory cells in a selected row. The row address decoder 103 (shown in FIG. 1) will activate all access transistors 303 in a selected row thereby coupling each storage device 301 in that row to their respective bit lines. The word lines 107 and bit lines 109 are manufactured using low temperature oxide deposition and metallization such that the integrity of the storage molecules 607 is preserved. In may be preferred to use room temperature deposition of silicon dioxide and metals to form these structures. Existing molecules are able to withstand temperatures in excess of 400 degrees Celsius, allowing a broad range of temperatures for subsequent processes.

The trench architecture shown in FIG. 6 avoids the possibility of metal being deposited onto the molecular layer, thereby preventing damage and other problems associated with other proposed architectures. The inside of the trench forms the electrode surface, and molecules form SAMs on the inside of the cylinder, hence, the number of molecules can be increased by increasing the depth of the trench. The height of each layer of metal determines the height of the trench, thereby allowing easy adjustment of the effective area of the two terminals. Because the vertical dimension is used, many more molecules (30 times that of a simple crossbar for a 200 nm thick electrode) are available for writing/reading. This allows greatly enhanced sensitivity for a given cross-sectional area. In addition, the design of FIG. 6 easily accomplishes any variation in the relative sizes of each electrode. The effective capacitance of each junction is diminished by the removal of a large area of dielectric between the two metal plates at each intersection. This may have an effect on the overall wire capacitance; however, if the lines are sufficiently thick, the wire resistance will not be impacted significantly.

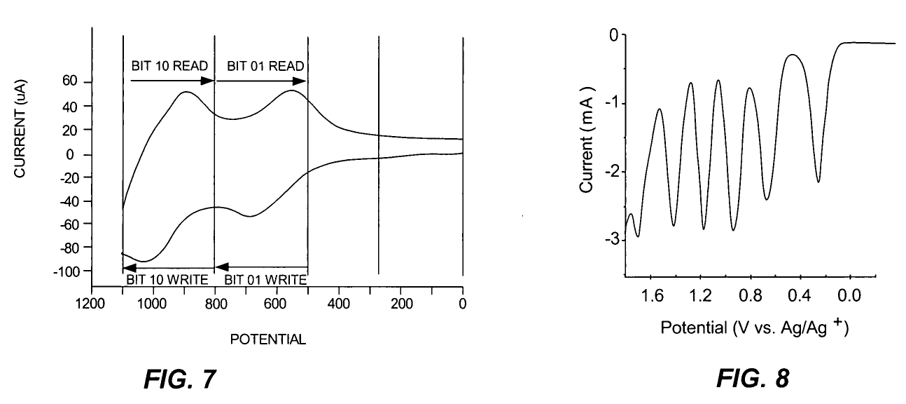

One advantage of molecular storage devices 301 is that molecular storage can readily be adapted to store multiple bits of data at each location by selection of the storage molecules. FIG. 7 is a cyclic voltammogram that illustrates a current-voltage characteristic of a two-state monomeric porphyrin storage molecule. The peaks and valleys correspond to distinct oxidation states that can be used for storing information. In the example of FIG. 7, two peaks correspond to two distinct oxidization states and therefore a storage device 301 that is capable of storing two states of information. Each oxidation state can be set or written to independently of the other. The lower portion of the cyclic curve corresponds to writing data to a molecular storage device 301 whereas the upper portion of the cyclic curve corresponds to reading data from a molecular storage device 301.

In order to write a state into the storage device 301 a voltage is applied to the bit line to create the desired oxidation state of the storage molecules. Typically, the voltage applied to the bit line will be somewhat more positive than the E_{1/2} of the molecule used in the MSD to compensate for resistive and capacitive losses in the writing circuitry. The losses associated with the writing circuitry are measurable and consistent, and so can be readily compensated. In a specific embodiment, the working electrode 502/602 is held at a ground potential and the reference electrode 511/611 is placed at a bias potential slightly below a peak in the IV curve shown in FIG. 7. The bit lines 109 are coupled to a write signal that indicates a first logic state with a voltage that when added to the bias potential is insufficient to cause oxidation of the storage molecules. The write signal indicates a second logic state with a voltage that when added to the bias potential is sufficient to cause oxidation of the storage molecules.

In the specific example of FIG. 7, the bias potential on reference electrode 511/611 is set at 500 mV and the data signal applied to a bit line is either 0 or 300 mV. A 500 mV signal is insufficient to cause oxidation, whereas an 800 mv signal is sufficient to cause oxidation of the first discrete oxidation state. To write a second state to the same storage device 301, the bias potential on reference electrode 511/611 is set above 800 mV. Once again, the data signal applied to a bit line is either 0 or 300 mV. An 800 mV signal is insufficient to cause oxidation, whereas an 1100 mV signal is sufficient to cause oxidation of the second discrete oxidation state. Hence, the first and second bits can be written subsequently.

After a write operation, the storage molecules will tend to remain at their oxidation state. In essence, the electrons added, or removed, by the write process are tightly bound to the storage molecules. In contrast, conventional solid state capacitors have electrons loosely captured in energy bands, where they are much more likely to escape. As a result, charge stored in storage molecules is much slower to leak away as compared to charge stored in a conventional capacitor. Once the storage molecules are written to a given oxidation state, they can be read by either voltage-mode sense amplifiers or current-mode sense amplifiers.

As shown in FIG. 7, one characteristic of storage molecules is that if a voltage is applied to molecular storage device 301, the current magnitude will vary distinctively depending on the oxidation state of the storage molecules. A peak in the CV curve shown in FIG. 7 corresponds to a particular oxidation state. If the storage molecules are already set at that particular oxidation state, no current will pass. For example, the storage device 301 can be read by applying a voltage between the reference electrode and the working electrode more positive than the characteristic peak in the CV curve shown in FIG. 7 and comparing the current to a reference current source. A relatively large current indicates a first logic state while a relatively low current indicates a second logic state. In this manner, the oxidation state of the storage molecules after a write is determined by the state of the write signal coupled to the bit line. Although the exemplary implementations write each bit serially, it is contemplated that the molecules can be written to and/or read from in parallel.

This reading methodology is partially or wholly destructive in that application of a potential during reading will alter the oxidation state of at least some storage molecules the storage device 301. Accordingly, a read operation is desirably followed by a write back to the molecular storage device 301 to restore the oxidation state of the storage molecules.

FIG. 8 illustrates a storage molecule having five discernable oxidation states, each indicated by a peak in the CV curve shown in FIG. 8. Molecular storage promises great expansion in information density because storage molecules can be designed to with almost any number of distinct oxidation states. As each oxidation state is capable of storing one bit if information the information density of a memory array increases dramatically. By implementing read/write logic, sense amplification mechanisms and the like that support molecular storage the present invention enables the use of these properties in practical memory devices.

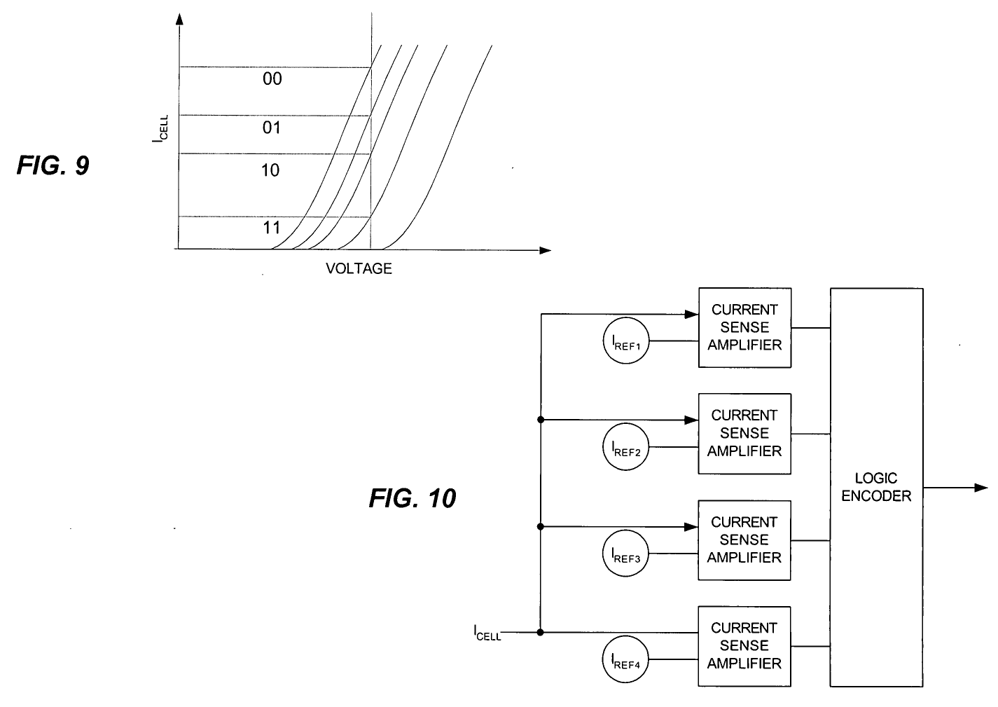

FIG. 9 illustrates an alternative view of the CV relationship of a storage device 301 having multiple distinct oxidation states. At any particular voltage the current is determined by the various oxidation states. Accordingly, reading a storage device 301 can be accomplished by applying a particular voltage to the storage device 301, measuring the current, and mapping the measured current to an appropriate logic state for the number of bits stored in the storage device 301.

FIG. 10 shows an exemplary current sense amplifier arrangement applicable to a multi-state molecular memory, although alternatively, a voltage sensing technique may likewise be employed. The arrangement shown in FIG. 10 implement parallel current sensing. The cell current (I_{CELL}) is coupled to a current-mode sense amplifier 1001. Cell current may be directly from a bit line 109, or may instead by pre-amplified. A pre-amplifier may be included within each current mode sense amplifier 1001 or provided separately. Each sense amplifier 1001 has a unique current referenced 1003 which indicates a threshold current value for a particular logic state. Each sense amplifier 1001 generates a binary signal indicating whether the cell current exceeded the reference current. Logic encoder 1005 receives the binary signals and maps them to logic signals, which may include level shifting, inverting, or processing with other combinatorial logic to meet the needs of a particular application.

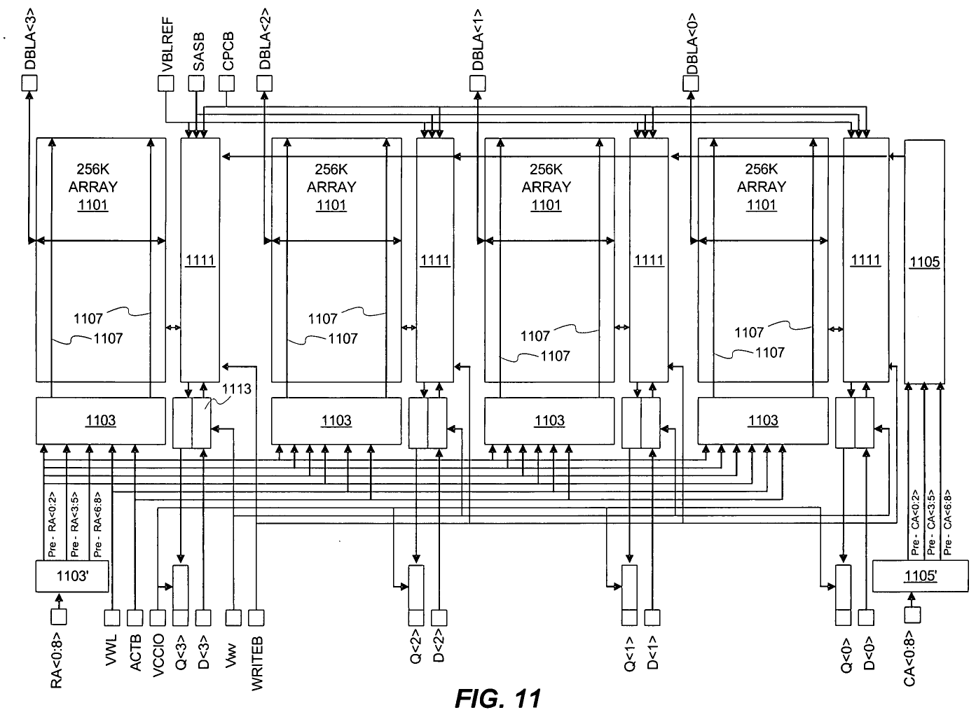

FIG. 11 illustrates a 1 Mbit implementation combining many of the molecular storage device features described hereinbefore into a practical large capacity memory. The layout shown in FIG. 11 follows industry standard pin out to the extent practicable. However, where multiple states are stored in each cell, it may be desirable to provide multiple pin outs so that data can be read out in parallel so that the read out consumes fewer clock cycles. The particular implementation of FIG. 11 uses four banks of memory cell arrays 1101 where each bank implements 256K memory locations arranged as 512 rows and 512 columns. The entire device shown in FIG. 11 has 512 rows×2048 columns or 1048576 locations (i.e., a 1 Mbit memory). Other arrangements of any size can be readily substituted for the particular arrangement shown in FIG. 11. To ease illustration, common chip inputs such as power supply voltages and ground are omitted.

An eight bit row address is supplied by an external device on the RA<0:8> input to row pre-decoder 1103′. Row pre-decoder partially decodes the row address and supplies the partially decoded output to each of row decoders 1103. A row decoder 1103 is supplied for each bank whereas the row pre-decoder 1103′ is typically shared amongst all of the banks. Row pre-decoder 1103 enables row decoders 1103 to be smaller and generally faster because they are processing addresses that are partially decoded. In the particular embodiment of FIG. 11, row decoders 1103 include word line driver circuitry for each word line. Column addresses are provided to the CA<0:8> input pin to a column address pre-decoder 1105′. Column address pre-decoder 1105′ supplies pre-decoded addresses to column decoder 1105, which generates the completely decoded addresses.

Each memory array 1101 includes 512 word lines 1107. A particular bank is selected for reading and/or writing by an appropriate signal placed on one of the DBLA lines shown in the upper portion of FIG. 4 which activates the bit line addressed by the column decoder 1105. A bit line reference voltage VBLREF is supplied to each of the sense amplifier modules 1111. The bit line reference voltage can be used for a voltage-mode sense amplification, or used to drive serial or parallel current-mode sense amplification.

Each memory array 1101 is provided with a sense amplification module 1111 which includes sense amplification circuitry coupled to the 512 bit lines of memory array 1101. Sense amplification module 1111 may also include write pass gates which enable data being written to memory array 1101 to bypass the sense amplifiers, as well as pre-charge pass gates which enables a bit line pre-charge signal (if used) to bypass the sense amplifiers. Bit line pre-charge is a useful technique for reducing the response time of bit lines by placing them at a potential just before reading that is midway between a high an low logic signal. This technique enables the bit line to respond more quickly because of the reduced voltage swing.

Data buffers 1103 serve to drive data signals onto bit lines during write operations, and to read data signals from bit lines during read operations. Logic 1005 for encoding multiple bits of data may be included in data buffer module 1103. Write data is received on the D< > inputs and read data output is placed on the Q<1>-Q<3> outputs. Although the implementation of FIG. 11 is generalized, it is apparent that the present invention enables the adaptation of DRAM circuit techniques and functional components to operate a molecular memory. This, in turn, existing circuit techniques to be leveraged into the much higher density provided by molecular storage devices.

Multi-electrode molehole arrays are well suited for use as memory elements in molecular based electronic devices and may be utilized in implementing the molecular memory arrays and devices of the present invention. In “molecular memory” elements redox-active molecules (molecules having one or more non-zero redox states) coupled to an electrode (e.g. the working electrode) in a molehole are used to store bits (e.g. in certain embodiments, each redox state can represent a bit or a combination of bits). The redox-active molecule attached to the electrode (e.g. silicon or germanium) forms a storage i cell capable of storing one or more bits in various oxidation states. In certain embodiments, the storage cell is characterized by a fixed working electrode electrically coupled to a “storage medium” comprising one or more redox-active molecules and having a multiplicity of different and distinguishable oxidation states. Data is stored in the (preferably non-neutral) oxidation states by the addition or withdrawal of one or more electrons from said storage medium via the electrically coupled electrode. The oxidation state of the redoxactive molecule(s) can be set and/or read using electrochemical methods (e.g. cyclic voltammetry), e.g., as described in U.S. Pat. Nos. 6,272,038, 6,212,093, and 6,208,553 and PCT Publication WO 01/03126, the disclosures of which are herein incorporated by this reference in their entirety. A molehole array comprising a plurality of moleholes (electrochemical cells) can provide a high capacity, high density memory device.

Because group N elements, in particular silicon and germanium, are commonly used in electronic chip fabrication, they readily lend themselves to the fabrication of molecular memory chips compatible with existing processing/fabrication technologies. In addition, details on the construction and use of storage cells comprising redox-active molecules can be found, in U.S. Pat. Nos. 6,272,038, 6,212,093, and 6,208,553 and PCT Publication WO 01/03126.

Certain preferred redox-active molecules suitable for use in accordance with the present invention are characterized by having a multiplicity of oxidation states. Those oxidation states are provided by one or more redox-active units. A redox-active unit refers to a molecule or to a subunit of a molecule that has one or more discrete oxidation states that can be set by application of an appropriate voltage. Thus, for example, the redox-active molecule can comprise two or more (e.g. 8) different and distinguishable oxidation states. Typically, but not necessarily, such multi-state molecules will be composed of several redox-active units (e.g. porphyrins or ferrocenes). Each redox-active molecule is itself at least one redox-active unit, or comprises at least one redox-active unit, but can easily comprise two or more redox-active units.

Preferred redox-active molecules include, but are not limited to porphyrinic macrocycles. The term “porphyrinic macrocycle” refers to a porphyrin or porphyrin derivative. Such derivatives include porphyrins with extra rings ortho-fused, or ortho-perifused, to the porphyrin nucleus, porphyrins having a replacement of one or more carbon atoms of the porphyrin ring by an atom of another element (skeletal replacement), derivatives having a replacement of a nitrogen atom of the porphyrin ring by an atom of another element (skeletal replacement of nitrogen), derivatives having substituents other than hydrogen located at the peripheral (meso-, (3-) or core atoms of the porphyrin, derivatives with saturation of one or more bonds of the porphyrin (hydroporphyrins, e.g., chlorins, bacteriochlorins, isobacteriochlorins, decahydroporphyrins, corphins, pyrrocorphins, etc.), derivatives obtained by coordination of one or more metals to one or more porphyrin atoms (metalloporphyrins), derivatives having one or more atoms, including pyrrolic and pyrromethenyl units, inserted in the porphyrin ring (expanded porphyrins), derivatives having one or more groups removed from the porphyrin ring (contracted porphyrins, e.g., corrin, corrole) and combinations of the foregoing derivatives (e.g. phthalocyanines, sub-phthalocyanines, and porphyrin isomers). Preferred porphyrinic macrocycles comprise at least one 5-membered ring.

The term “porphyrin” refers to a cyclic structure typically composed of four pyrrole rings together with four nitrogen atoms and two replaceable hydrogens for which various metalatoms can readily be substituted. A typical porphyrin is hemin.

Particularly preferred redox-active molecules include a porphyrin, an expanded porphyrin, a contracted porphyrin, a ferrocene, a linear porphyrin polymer, a porphyrin sandwich coordination complex, and a porphyrin array.

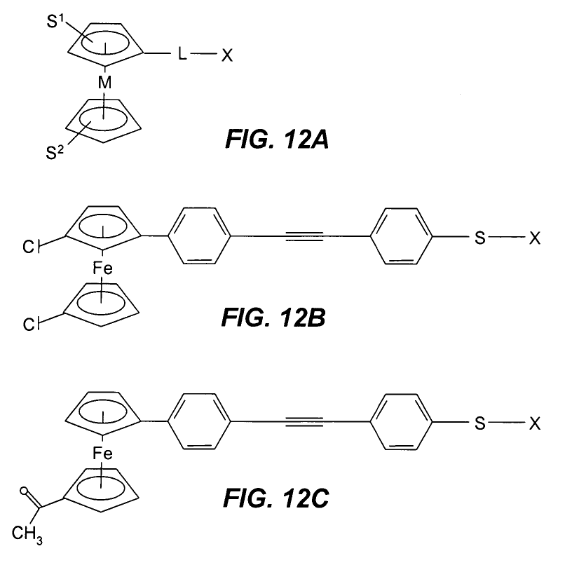

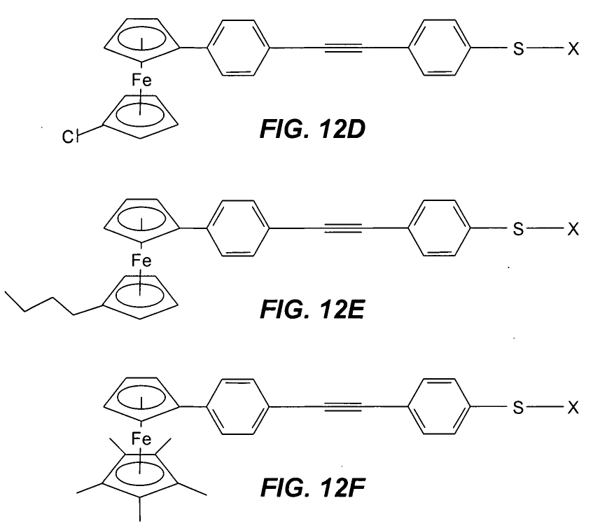

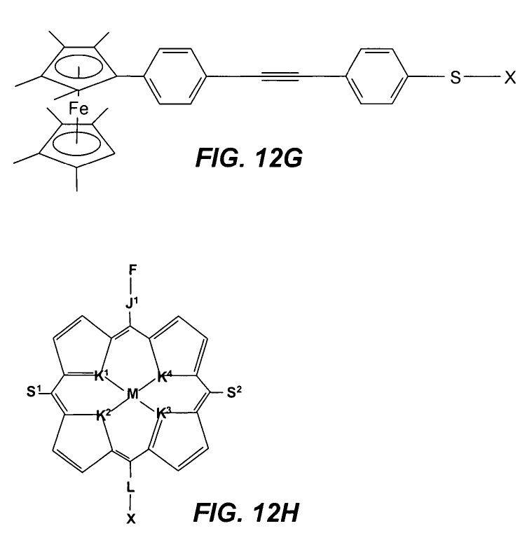

In one preferred embodiment, the redox-active molecule may be a metallocene as shown in the formula of FIG. 12A where L is a linker, M is a metal (e.g., Fe, Ru, Os, Co, Ni, Ti, Nb, Mn, Re, V, Cr, W), S′ and SZ are substituents independently selected from the group consisting of aryl, phenyl, cycloalkyl, alkyl, halogen, alkoxy, alkylthio, perfluoroalkyl, perfluoroaryl, pyridyl, cyano, thiocyanato, nitro, amino, alkylamino, acyl, sulfoxyl, sulfonyl, imido, amido, and carbamoyl. In preferred embodiments, a substituted aryl group is attached to the porphyrin, and the substituents on the aryl group are selected from the group consisting of aryl, phenyl, cycloalkyl, alkyl, halogen, alkoxy, alkylthio, perfluoroalkyl, perfluoroaryl, pyridyl, cyano, thiocyanato, nitro, amino, alkylamino, acyl, sulfoxyl, sulfonyl, imido, amido, and carbamoyl.

Particularly preferred substituents include, but are not limited to, 4chlorophenyl, 3-acetamidophenyl, 2,4-dichloro-4-trifluoromethyl. Preferred substituents provide a redox potential range of less than about 2 volts. X is selected from the group consisting of a substrate, a reactive site that can covalently couple to a substrate (e.g. an alcohol, a thiol, etc.). It will be appreciated that in some embodiments, L-X may be an alcohol or a thiol. In certain instances L-X can be replaced with another substituent (S3) like S 1 or S2. In certain embodiments, L-X can be present or absent, and when present preferably is 4-hydroxyphenyl, 4-(2-(4-hydroxyphenyl)ethynyl)phenyl, 4-hydroxymethyl)phenyl, 4-mercaptophenyl, 4-(2-(4-mercaptophenyl)ethynyl)phenyl, 4-(mercaptomethyl)phenyl, 4-hydroselenophenyl, 4-(2-(4-hydroselenophenyl)ethynyl)phenyl, 4-(hydroselenylmethyl)phenyl, 4-hydrotellurophenyl, 4-(2-(4-hydrotellurophenyl)ethynyl)phenyl, and 4-(hydrotelluromethyl)phenyl.

The oxidation state of molecules of the formula of FIG. 12A is determined by the metal and the substituents. Thus, particular preferred embodiments are illustrated by the formulae of FIGS. 12B-12G.

The ferrocenes listed above in the formulae of these figures provide a convenient series of one-bit molecules having different and distinguishable oxidation states. Thus the molecules of these formulae have oxidation states (Eli2) of +0.55 V, +0.48V, +0.39 V, +0.17 V, −0.05 V, and −0.18 V, respectively, and provide a convenient series of molecules for incorporation into a storage medium of this invention. It will be appreciated that the oxidation potentials of the members of the series can be routinely altered by changing the metal (M) or the substituents.

Another preferred redox-active molecule is a porphyrin illustrated by the formula of FIG. 12H where, F is a redox-active subunit (e.g., a ferrocene, a substituted ferrocene, a metalloporphyrin, or a metallochlorin, etc.), J1 is a linker, M is a metal (e.g., Zn, Mg, Cd, Hg, Cu, Ag, Au, Ni, Pd, Pt, Co, Rh, Ir, Mn, B, Al, Ga, Pb, and Sn), S1 and S2 are independently selected from the group consisting of aryl, phenyl, cycloalkyl, alkyl, halogen, alkoxy, alkylthio, perfluoroalkyl, perfluoroaryl, pyridyl, cyano, thiocyanato, nitro, amino, alkylamino, acyl, sulfoxyl, sulfonyl, imido, amido, and carbamoyl wherein said substituents provide a redox potential range of less than about 2 volts, K1, KZ, K3, and K4 are independently selected from the group consisting of N, O, S, Se, Te, and CH; L is a linker; X is selected from the group consisting of a substrate, a reactive site that can covalently couple to a substrate, and a reactive site that can ionically couple to a substrate. In preferred embodiments, X or L-X may be an alcohol or a thiol. In some embodiments L-X can be eliminated and replaced with a substituent independently selected from the same group as S1 or S2.

Control over the hole-storage and hole-hopping properties of the redox-active units of the redox-active molecules used in the memory devices of the present invention allows fine control over the architecture of the memory device.

Such control is exercised through synthetic design. The hole-storage properties depend on the oxidation potential of the redox-active units or subunits that are themselves or are that are used to assemble the storage media used in the devices of this invention. The hole-storage properties and redox potential can be tuned with precision by choice of base molecule(s), associated metals and peripheral substituents (Yang et al. (1999) J. Porphyrins Phthalocyanines, 3: 117-147), the disclosure of which is herein incorporated by this reference.

For example, in the case of porphyrins, Mg porphyrins are more easily i oxidized than Zn porphyrins, and electron withdrawing or electron releasing aryl groups can modulate the oxidation properties in predictable ways. Hole-hopping occurs among isoenergetic porphyrins in a nanostructure and is mediated via the covalent linker joining the porphyrins (Seth et al. (1994) J. Am. Chem. Soc., 116: 10578-10592, Seth et al (1996) J. Am. Chem. Soc., 118: 11194-11207, Strachan et al. (1997) J. Am. Chem. Soc., 119: 11191-11201; Li et al. (1997) J. Mater. Chem., 7: 1245-1262, Strachan et al. (1998) Inorg. Chem., 37: 1191-1201, Yang et al. (1999) J. Am. Chem. Soc., 121: 4008-4018), the disclosures of which are herein specifically incorporated by this reference in their entirety.

The design of compounds with predicted redox potentials is well known to those of ordinary skill in the art. In general, the oxidation potentials of redox-active units or subunits are well known to those of skill in the art and can be looked up (see, e.g., Handbook of Electrochemistry of the Elements). Moreover, in general, the effects of various substituents on the redox potentials of a molecule are generally additive. Thus, a theoretical oxidation potential can be readily predicted for any potential data storage molecule. The actual oxidation potential, particularly the oxidation potential of the information storage molecule(s) or the information storage medium can be measured according to standard methods. Typically the oxidation potential is predicted by comparison of the experimentally determined oxidation potential of a base molecule and that of a base molecule bearing one substituent in order to determine the shift in potential due to that particular substituent. The sum of such substituent-dependent potential shifts for the respective substituents then gives the predicted oxidation potential.

Various preferred redox-active molecules and the syntheses thereof are described in detail in U.S. Pat. Nos. 6,272,038, 6,212,093, and 6,208,553 and PCT Publication WO 01/03126, previously mentioned.

Although the invention has been described and illustrated with a certain degree of particularity, it is understood that the present disclosure has been made only by way of example, and that numerous changes in the combination and arrangement of parts can be resorted to by those skilled in the art without departing from the spirit and scope of the invention, as hereinafter claimed.

1. A molecular memory element comprising:
a switching device;
a bit line and a word line coupled to the switching device; and
a molecular storage device comprising a first electrode, a second electrode and a molecular material between the first and second electrodes, wherein the switching device is coupled to the first electrode.

2. The molecular memory array of claim 1, wherein the switching device comprises a transistor.

3. The molecular memory array of claim 2, wherein the transistor comprises a field effect transistor.

4. The molecular memory array of claim 1, comprising a row decoder coupled to the word line.

5. The molecular memory array of claim 1, comprising a column decoder coupled to the bit line.

6. The molecular memory array of claim 1, comprising a current preamplifier connected to the bit line.

7. The molecular memory array of claim 1, comprising a sense amplifier connected to the bit line.

8. The molecular memory array of claim 1, wherein the second electrode of the molecular storage device is coupled to ground.

9. The molecular memory array of claim 8, wherein the array comprises volatile memory.

10. The molecular memory array of claim 9 wherein the volatile memory comprises one of DRAM or SRAM.

11. The molecular memory array of claim 8, wherein the array comprises non-volatile memory.

12. The molecular memory array of claim 11 wherein the volatile memory comprises one of Flash or ferroelectric memory.

13. The molecular memory array of claim 1, wherein the molecular storage device comprises:
an attachment layer formed on the first electrode, wherein the attachment layer comprises an opening and wherein the molecular material is in the opening and electronically coupled to the second electrode layer; and
an electrolyte layer formed on the attachment layer.

14. The molecular memory of claim 1, wherein the molecular material comprises a molecular storage layer comprising one or more storage molecules.

15. The molecular memory of claim 1, wherein the molecular material comprises at least one molecule selected from a group comprising a porphyrinic macrocycle, a metallocene, a linear polyene, a cyclic polyene, a heteroatom-substituted linear polyene, a heteroatom substituted cyclic polyene, a tetrathiafulvalene, a tetraselenafulvalene, a metal coordination complex, a buckyball, a triarylamine, a 1,4-phenylenediamine, a xanthene, a flavin, a phenazine, a phenothiazine, an acridine, a quinoline, a 2,2′=bipyridyl, a 4,4′-bipyridyl, a tetrathiotetracene or a peri-bridged naphthalene dichalcogenide.

16. The molecular memory of claim 1, wherein the molecular material comprises at least one molecule selected from a group comprising a porphyrin, an expanded porphyrin, a contracted porphyrin, a ferrocene, a linear porphyrin polymer, a porphyrinic sandwich complex or a porphyrin array.

17. The molecular memory of claim 1, wherein the molecular material is coupled to an electrode with a linker.

18. The molecular memory of claim 15, wherein the molecular material provides at least four oxidation states.

19. The molecular memory of claim 12, wherein the molecular material provides at least six oxidation states.

20. The molecular memory of claim 1, wherein the first electrode and the second electrode comprise a metal or a semiconductor.

21. The molecular memory of claim 20, wherein the metal comprises Al, Au, Ag, Ti, W, Cu or oxides or nitrides of metals.

22. The molecular memory of claim 20, wherein the semiconductor comprises Si, Ge, SiGe, GaAs, or ITO.

23. The molecular memory of claim 1, wherein the molecular storage device has a charge retention time of greater than 64 msec.

24. The molecular memory of claim 1, wherein the molecular storage device has a charge retention time determined by the intrinsic properties of the molecule.

25. The molecular memory of claim 24 wherein the molecular storage device has a charge retention time of greater than 64 msec.

26. The molecular memory device of claim 1, wherein the bit line and the word line are perpendicular.

27. The molecular memory device of claim 1, wherein the bit line and the word line are parallel.

28. A molecular memory array comprising:
a plurality of molecular storage elements where each molecular storage element is capable of being placed in two or more discrete states.

29. The molecular memory array of claim 28 further comprising:
a plurality of bit lines and word lines coupled to the plurality of molecular storage elements such that each molecular storage element is coupled to and addressable by at least one bit line and at least one word line.

30. A molecular memory device comprising:
an addressable array of molecular storage elements.

31. The molecular memory device of claim 30 further comprising an address decoder that receives a coded address and generates word line signals corresponding to the coded address.

32. The molecular memory device of claim 31 further comprising a line driver coupled to the address decoder wherein the line driver produces amplified word line signals.

33. The molecular memory device of claim 32 wherein the amplified word line signals control switches that selectively couple members of the array of molecular storage elements to bit lines.

34. The molecular memory device of claim 33 wherein read/write logic coupled to the bit lines, wherein the read/write logic determines whether the molecular memory devices is in a read mode or a write mode.

35. The molecular memory device of claim 33 further comprising sense amplifiers coupled to each bit line, wherein when the device is in a read mode, sense amplifiers coupled to each bit line detect an electronic state of the selectively coupled molecular storage elements and produce a data signal on the bit line indicative of the electronic state of the selectively coupled molecular storage elements.

36. The molecular memory device of claim 33 wherein when the device is in a write mode, the read/write logic drives a data signal onto the bit lines and the selectively coupled molecular storage elements.

37. An monolithically integrated device comprising:
logic devices configured to perform a particular function; and
embedded molecular memory devices coupled to the logic devices.

38. The monolithically integrated device of claim 37 wherein the device comprises an application specific integrated circuit (ASIC)

39. The monolithically integrated device of claim 37 wherein the device comprises a system on chip (SOC).

40. The monolithically integrated device of claim 37 wherein the logic devices comprise solid state electronic devices.

41. The monolithically integrated device of claim 37 wherein the logic devices comprise molecular electronic devices.
